(19) United States
(12) Patent Application Publication
(10) Pub. No.: US 2026/0030399 A1
(43) Pub. Date: Jan. 29, 2026

(54) COLOR BALANCE CALCULATION SYSTEM, COLOR BALANCE CALCULATION METHOD, AND COLOR BALANCE CALCULATION PROGRAM

(71) Applicant: Sekisui House, Ltd., Osaka (JP)

(72) Inventors: Yukako Komoto, Osaka-shi (JP); Kazumi Maehara, Osaka-shi (JP); Naoko Yano, Osaka-shi (JP); Nao Adachi, Osaka-shi (JP)

(73) Assignee: Sekisui House, Ltd., Osaka (JP)

(21) Appl. No.: 19/342,335

(22) Filed: Sep. 26, 2025

Related U.S. Application Data
(63) Continuation-in-part of application No. PCT/JP2023/030478, filed on Aug. 24, 2023.

(30) Foreign Application Priority Data
Mar. 31, 2023 (JP) 2023-057336

(51) Int. Cl. G06F 30/13

(52) U.S. Cl. CPC G06F 30/13

(57) ABSTRACT

A color balance calculation system includes an acquisition unit and a calculation unit that calculates a color balance. The calculation unit calculates the sum of areas of a first system color, the sum of areas of a second system color, and the sum of areas of an accent color on the basis of a base exposed area that is visible on a base surface, the color of the base surface, an object exposed area that is visible on each placed object, and the color of each placed object. The calculation unit calculates the ratio of the sum of the areas of the first system color to the sum of the areas of the second system color to the sum of the areas of the accent color as a color balance.

### CROSS-REFERENCE TO RELATED APPLICATIONS

This application is a continuation in part of, and claims the benefit of priority from International Application No. PCT/JP2023/030478, filed on Aug. 24, 2023, which claims the benefit of priority from Japanese Patent Application No. 2023-057336, filed on Mar. 31, 2023, the entire contents of each of which are incorporated herein by reference.

### TECHNICAL FIELD

The present disclosure relates to a color balance calculation system, a color balance calculation method, and a color balance calculation program for use in buildings.

### BACKGROUND ART

Designers of buildings design interiors while taking color balance into consideration. JP2005-157809A discloses a technique in which interior design is carried out using a predefined color scheme. In interior design, the surface area ratio of base colors serving as the base tone of the interior, secondary colors, which occupy the next largest surface area following the base colors, and accent colors, which add visual emphasis, are considered.

### SUMMARY

### Technical Problem

Conventionally, designers determine the color of each interior component based on their experience, intuition, or a predefined color scheme. However, in practice, these color choices are often made without quantifying the surface area ratio of each color across the entire interior space. Therefore, it is difficult to objectively evaluate the surface area ratio of the colors in the entire interior during the design phase and after the design phase.

### Solution to Problem

(1) To achieve the foregoing objective, a color balance calculation system calculates a color balance of an interior of a target region in a building. The system includes an acquisition unit that acquires interior data representing the interior, and a calculation unit that calculates the color balance based on the interior data. The interior data includes color information and shape information of each of multiple components forming the interior. The components include a base surface facing the target region, and a placed object arranged in the target region. The calculation unit calculates a total surface area of a first color family and a total surface area of a second color family based on a visible exposed base surface area of the base surface, a color of the base surface, a visible exposed object surface area of the placed object, and a color of the placed object, and further calculates, as the color balance, a ratio of the total surface area of the first color family and the total surface area of the second color family. Alternatively, the calculation unit calculates the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object, and further calculates, as the color balance, a ratio of the total surface area of the first color family, the total surface area of the second color family, and the total surface area of the accent color family.

This configuration allows the color balance of the target region to be calculated. The color balance is calculated based on the exposed surface areas of visible parts of the base surface and the placed object. This allows for calculation of a color balance that more closely reflects human perception than a calculation based solely on the surface areas of the base surface and the placed object.

(2) In the color balance calculation system of the above item (1), in a case in which the placed object is placed so as to be in contact with the base surface, the calculation unit calculates, as the exposed base surface area, a value obtained by subtracting a contact area of a portion of the placed object that is in contact with the base surface from a base surface area of the base surface. This configuration excludes portions of the base surface that are not visible from the exposed base surface area. This improves the accuracy of the color balance.

(3) In the color balance calculation system of the above item (2), in a case in which an opening is provided in the base surface, the calculation unit calculates, as the exposed base surface area, a value obtained by subtracting an opening area of the opening from the base surface area of the base surface. With this configuration, the opening in the base surface is excluded from the exposed base surface area. This improves the accuracy of the color balance.

(4) In the color balance calculation system of any of the above items (1) to (3), each of a first surface forming a bottom surface of the target region, a second surface intersecting the first surface, a third surface located at an end opposite to the second surface, a fourth surface connected to the second surface and the third surface, a fifth surface located at an end opposite to the fourth surface, and a sixth surface forming a ceiling surface of the target region is defined as the base surface. This configuration simplifies the calculation of the surface area of the base surface and the exposed base surface area.

(5) In the color balance calculation system of any one of the above items (1) to (4), a surface of the placed object viewed from a first direction facing the first surface is defined as an eleventh surface. A surface of the placed object viewed from a second direction facing the second surface is defined as a twelfth surface. A surface of the placed object viewed from a third direction facing the third surface is defined as a thirteenth surface. A surface of the placed object viewed from a fourth direction facing the fourth surface is defined as a fourteenth surface. A surface of the placed object viewed from a fifth direction facing the fifth surface is defined as a fifteenth surface. A surface of the placed object viewed from a sixth direction facing the sixth surface is defined as a sixteenth surface. The calculation unit calculates, as the exposed object surface area, a surface area of at least one of the eleventh surface through the sixteenth surface of the placed object. This configuration simplifies the calculation of the exposed object surface area of the placed object.

(6) The color balance calculation system of any one of the above items (1) to (5) further includes a color modification unit that changes the color of the base surface and the color of the placed object. This configuration allows the color balance of the interior of the target region to be readily changed.

(7) To achieve the foregoing objective, a color balance calculation system calculates a color balance of an interior of a target region in a building. The system includes an acquisition unit that acquires interior data representing the interior, and a calculation unit that calculates the color balance based on the interior data. The interior data includes color information and shape information of each of multiple components forming the interior. The components include a base surface facing the target region, and a placed object arranged in the target region. The calculation unit calculates, as the color balance, a ratio of surface areas of multiple color families based on a visible exposed base surface area of the base surface, a color of the base surface, a visible exposed object surface area of the placed object, and a color of the placed object.

This configuration allows the color balance of the target region to be calculated. The color balance is calculated based on the exposed surface areas of visible parts of the base surface and the placed object. This allows for calculation of a color balance that more closely reflects human perception than a calculation based solely on the surface areas of the base surface and the placed object.

(8) To achieve the foregoing object, a color balance calculation method for calculating a color balance of an interior of a target region in a building includes an acquisition step that acquires interior data representing the interior, and a calculation step that calculates the color balance based on the interior data. The interior data includes color information and shape information of each of multiple components forming the interior. The components include a base surface facing the target region, and a placed object arranged in the target region. The calculation step calculates a total surface area of a first color family and a total surface area of a second color family based on a visible exposed base surface area of the base surface, a color of the base surface, a visible exposed object surface area of the placed object, and a color of the placed object, and further calculates, as the color balance, a ratio of the total surface area of the first color family and the total surface area of the second color family. Alternatively, the calculation step calculates the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculates, as the color balance, a ratio of the total surface area of the first color family, the total surface area of the second color family, and the total surface area of the accent color family.

This configuration allows the color balance of the target region to be calculated. The color balance is calculated based on the exposed surface areas of visible parts of the base surface and the placed object. This allows for calculation of a color balance that more closely reflects human perception than a calculation based solely on the surface areas of the base surface and the placed object.

(9) To achieve the foregoing objective, a color balance calculation program causes a computer to calculate a color balance of an interior of a target region in a building. The program includes an acquisition process that causes the computer to acquire interior data representing the interior, and a calculation process that causes the computer to calculate the color balance based on the interior data. The interior data includes color information and shape information of each of multiple components forming the interior. The components include a base surface facing the target region, and a placed object arranged in the target region. The calculation process causes the computer to calculate a total surface area of a first color family and a total surface area of a second color family based on a visible exposed base surface area of the base surface, a color of the base surface, a visible exposed object surface area of the placed object, and a color of the placed object, and further calculate, as the color balance, a ratio of the total surface area of the first color family and the total surface area of the second color family. Alternatively, the calculation process causes the computer to calculate the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculate, as the color balance, a ratio of the total surface area of the first color family, the total surface area of the second color family, and the total surface area of the accent color family.

This configuration allows the color balance of the target region to be calculated. It is also possible to cause the computer to calculate the color balance based on the exposed surface areas of visible parts of the base surface and the placed object. This causes the computer to calculate a color balance that more closely reflects human perception than a calculation based solely on the surface areas of the base surface and the placed object.

### Advantageous Effects

According to the present disclosure, the color balance can be calculated.

### BRIEF DESCRIPTION OF DRAWINGS

FIG. 1 is a schematic diagram of an interior of a target region as viewed from a prescribed direction.

FIG. 2 is a schematic diagram of an interior of a target region as viewed from a direction different from the prescribed direction.

FIG. 3 is a block diagram of a color balance calculation system.

FIG. 4 is a diagram showing first through sixth surfaces of a target region.

FIG. 5 is a diagram showing portions in contact with placed objects and opening portions in FIG. 4.

FIG. 6 is a diagram showing eleventh through sixteenth surfaces of a counter.

FIG. 7 is a table showing data used to calculate an exposed base surface area of the first surface.

FIG. 8 is a table showing data used to calculate an exposed base surface area of the second surface.

FIG. 9 is a table showing data used to calculate an exposed base surface area of the third surface.

FIG. 10 is a table showing data used to calculate an exposed base surface area of the fourth surface.

FIG. 11 is a table showing data used to calculate an exposed base surface area of the fifth surface.

FIG. 12 is a table showing data used to calculate an exposed base surface area of a sixth surface.

FIG. 13 is a diagram showing color families of components.

FIG. 14 is a table showing the exposed surface areas of the components, the surface areas of the respective color families, and the color balance of the interior.

FIG. 15 is a diagram showing a color modification unit.

FIG. 16 is a diagram showing a database of components.

### DESCRIPTION OF EMBODIMENTS

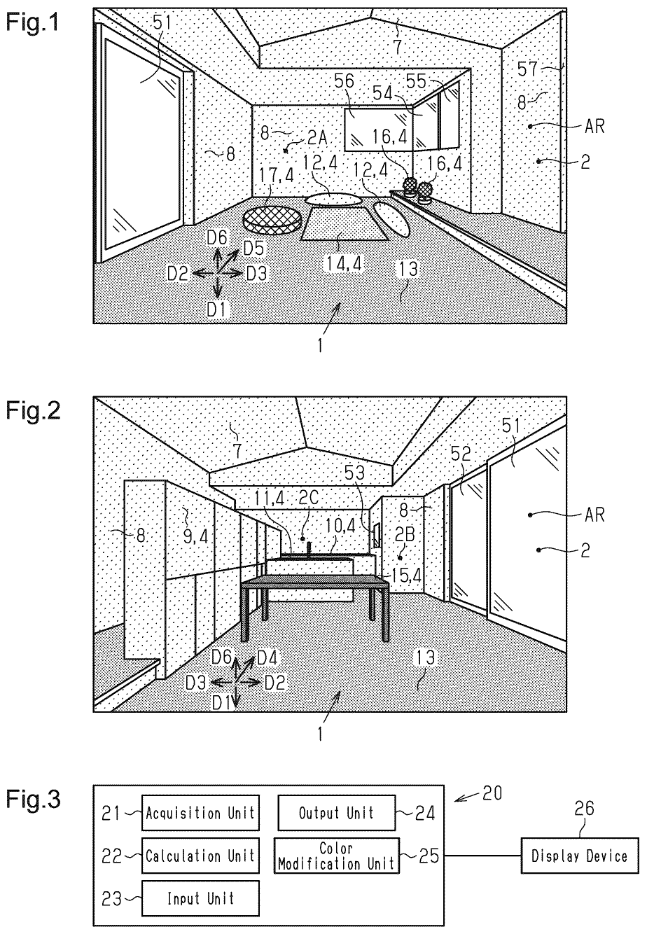

A color balance calculation system 20 according to the present embodiment will now be described with reference to FIGS. 1 through 15. The color balance calculation system 20 calculates a color balance CB of an interior 1 of a target region AR in a building.

The color balance CB will be described with reference to FIGS. 1 and 2. FIGS. 1 and 2 show a room 2 of the building. The target region AR for calculation of the color balance CB is a space surrounded by partitions such as walls. Examples of the target region AR include a living room, a dining room, a combined kitchen-dining area, a combined living-dining area, a combined living-dining-kitchen area, a child's room, a workspace, a hallway, a space with stairs, and a space with an open ceiling.

The colors of the interior 1 of the room 2 are determined by the surrounding surfaces of the room 2 (hereinafter, referred to as base surfaces 3), and objects 4 placed in the room 2. Examples of the base surfaces 3 include a floor surface, a ceiling surface, and wall surfaces. Examples of the placed objects 4 include a table, a chair, a cushion, a shelf, a plant, a rug such as a carpet, a curtain, a clock, a decorative item, an artwork, a worktop such as a kitchen counter, and an electric appliance. Examples of electric appliances include an air conditioner, a television, a microwave oven, and a refrigerator.

In the color coordination of the interior 1, color balance is important. In the color coordination of the interior 1, the surface area ratio of colors of different families (hereinafter, referred to as color families) is considered. In one example, the dominant colors in the interior 1 are defined as base colors. In the interior 1, colors having the next largest surface area following the base colors are defined as secondary colors. In the interior 1, colors that are neither the base colors nor the secondary colors, and are visually prominent are defined to belong to an accent color family AC. In the present embodiment, the base colors are also referred to as colors belonging to a first color family C1. The secondary colors are also referred to as colors belonging to a second color family C2. In the color coordination of the interior 1, the colors of the base surfaces 3 or the placed objects 4 are determined such that the surface area ratio of the first color family C1, the second color family C2, and the accent color family AC is a prescribed ratio. The number of color families for which the surface area ratio is considered in the color coordination of the interior 1 is not limited to three. The surface area ratio of the first color family C1 and the second color family C2 may be considered as the color balance CB. The surface area ratio of four or more color families may be considered as the color balance CB.

An example of the color balance CB of the first color family C1 (base colors), the second color family C2 (secondary colors), and the accent color family AC will be described. The ratio of the first color family C1 (base colors) is set in a range of 63% to 78% in relation to the total surface area. The ratio of the second color family C2 (secondary colors) is set in a range of 20% to 30% in relation to the total surface area. The ratio of the accent color family AC is set in a range of 2% to 7% in relation to the total surface area. The total surface area represents the combined surface area of surfaces visible within the target region AR.

FIGS. 1 and 2 show the room 2, which includes a combined living-dining-kitchen area. The combined living-dining-kitchen area is the room 2, which includes a living room 2A, a dining room 2B, and a kitchen 2C. In the room 2, a divider shelf 9, a kitchen counter 10, a counter 11, cushions 12, a rug 14, a dining table 15, potted plants 16, and a living room table 17 are arranged. In this example, a ceiling surface 7, walls 8, the divider shelf 9, the kitchen counter 10, the counter 11, and the cushions 12 have white-based colors. In the interior 1, the white-based colors occupy the largest surface area. In the interior 1, the colors having the largest surface area after the white-based colors are beige-based colors. The floor surface 13, the rug 14, and the dining table 15 are beige. As items belonging to the accent color family AC, the room 2 includes the potted plants 16 and the living room table 17, which is gray.

The color balance CB is identified by generating a perspective rendering of the room 2. The color scheme is then adjusted based on subjective impressions of the designer or the client. Through this method, the color coordination of the interior 1 is adjusted to meet the client's requirements.

As described above, although the color coordination of the interior 1 involves consideration of the surface area ratio of the respective color families, the actual surface area ratio of the color families in the finalized design of the interior 1 is often unknown. Additionally, during the color coordination process, changes in the surface area ratio of the color families may not be tracked. Consequently, in the color coordination of the interior 1, although the surface area ratio of the color families is considered, the surface area ratio of the color families is adjusted only subjectively based on perceived dominance. The color balance calculation system 20, capable of calculating the color balance CB, will now be described.

### Color Balance Calculation System

As shown in FIG. 3, the color balance calculation system 20 includes an acquisition unit 21 and a calculation unit 22. The color balance calculation system 20 may include an input unit 23. The color balance calculation system 20 may include an output unit 24. The color balance calculation system 20 may include a color modification unit 25.

The acquisition unit 21 acquires interior data, which is data of the interior 1. In one example, the acquisition unit 21 acquires the interior data from computer-aided design (CAD) data of the building. The interior data includes color information and shape information for each of multiple components forming the interior 1. The components include the base surfaces 3, facing the target region AR, and the objects 4 placed in the target region AR.

The interior data is formed from the CAD data. Alternatively, the interior data may be formed from spreadsheet data.

### Calculation Unit

The calculation unit 22 calculates the color balance CB based on the interior data. The calculation unit 22 will now be described below. The calculation unit 22 defines each surface of the target region AR as a base surface 3 based on the interior data.

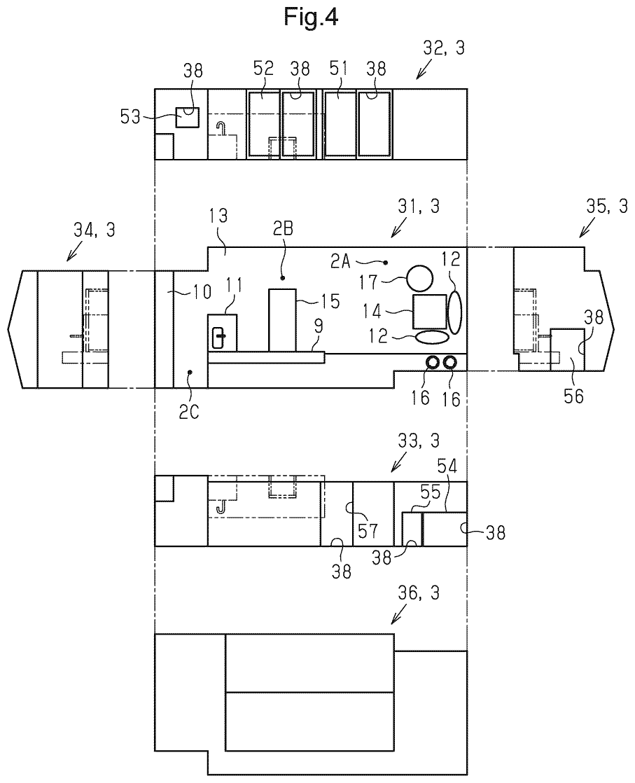

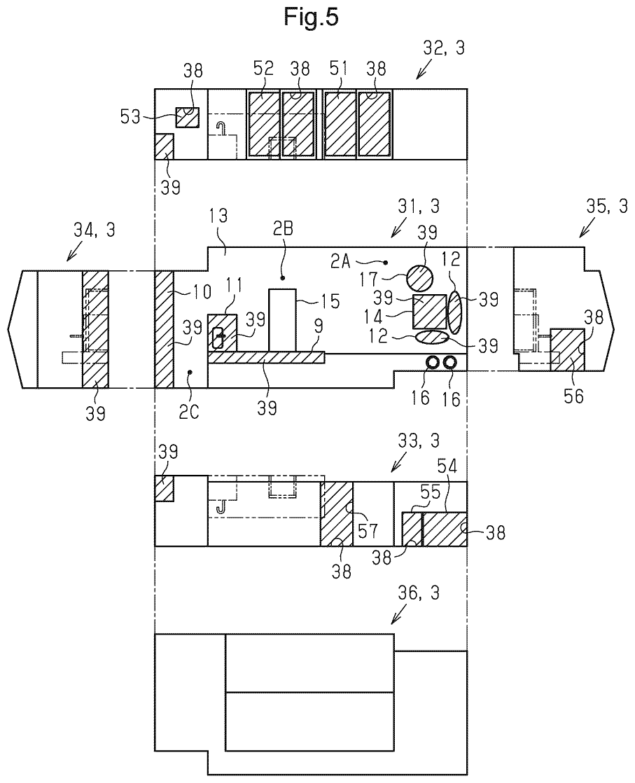

The relationship between the respective surfaces of the target region AR and the base surfaces 3 will be described with reference to FIGS. 4 and 5.

The calculation unit 22 defines a first surface 31 forming the bottom surface (floor surface 13) of the target region AR as one of the base surfaces 3. A second surface 32 intersecting the first surface 31 is defined as one of the base surfaces 3. A third surface 33 located at an end opposite to the second surface 32 is defined as one of the base surfaces 3. A fourth surface 34 connected to the second surface 32 and the third surface 33 is defined as one of the base surfaces 3. A fifth surface 35 located at an end opposite to the fourth surface 34 is defined as one of the base surfaces 3. A sixth surface 36 forming the ceiling surface 7 of the target region AR is defined as one of the base surfaces 3.

Each surface of the target region AR may be defined by user operation. For example, the first surface 31 through the sixth surface 36 are specified through operation of the input unit 23. The specified first through sixth surfaces 31-36 are each defined as one of the base surfaces 3 by user operation.

In calculation of the color balance CB, all of the first surface 31 through the sixth surface 36 of the target region AR may be used. Alternatively, in calculation of the color balance CB, any one or more of the first surface 31 through the sixth surface 36 of the target region AR may be used. For example, if a relatively large opening 38 is provided in the second surface 32, among the first surface 31 through the sixth surface 36, and the second surface 32 does not contribute to the interior 1, the calculation of the color balance CB may exclude the calculation for the second surface 32.

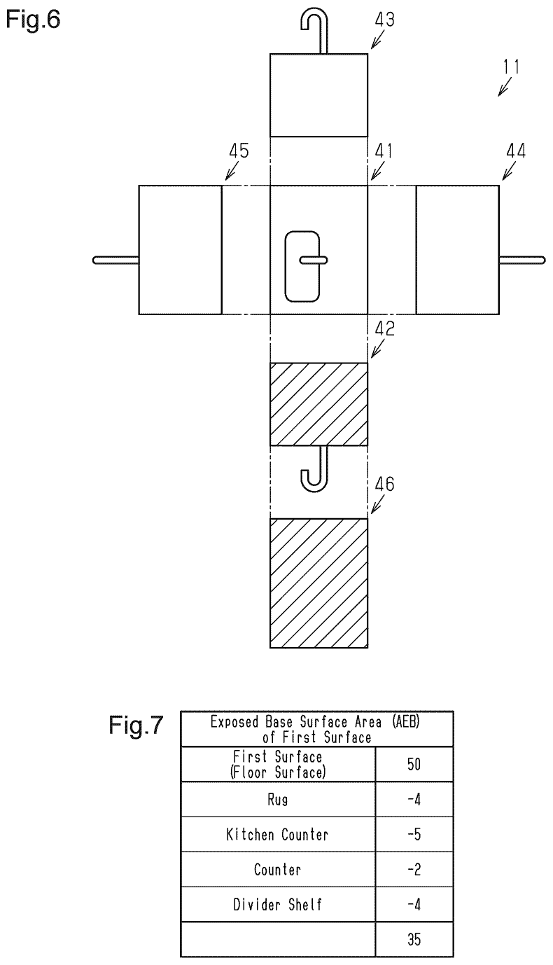

With reference to FIG. 6, the definition of surfaces forming the surfaces of a placed object 4 will be described. The calculation unit 22 defines surfaces of a placed object 4 viewed from prescribed directions as follows. The calculation unit 22 defines surfaces of the placed object 4 with reference to the surfaces defined for the target region AR. FIG. 6 illustrates an eleventh surface 41 through a sixteenth surface 46 of the counter 11.

A surface of each placed object 4 viewed from a first direction D1 facing the first surface 31 is defined as an eleventh surface 41. A surface of the placed object 4 viewed from a second direction D2 facing the second surface 32 is defined as a twelfth surface 42. A surface of the placed object 4 viewed from a third direction D3 facing the third surface 33 is defined as a thirteenth surface 43. A surface of the placed object 4 viewed from a fourth direction D4 facing the fourth surface 34 is defined as a fourteenth surface 44. A surface of the placed object 4 viewed from a fifth direction D5 facing the fifth surface 35 is defined as a fifteenth surface 45. A surface of the placed object 4 viewed from a sixth direction D6 facing the sixth surface 36 is defined as a sixteenth surface 46.

In FIG. 6, the twelfth surface 42 of the placed object 4 is depicted as a projection onto the third surface 33 of the target region AR. The thirteenth surface 43 of the placed object 4 is depicted as a projection onto the second surface 32 of the target region AR. The fourteenth surface 44 of the placed object 4 is depicted as a projection onto the fifth surface 35 of the target region AR. The fifteenth surface 45 of the placed object 4 is depicted as a projection onto the fourth surface 34 of the target region AR.

In the example shown in the present embodiment, the twelfth surface 42 of the counter 11 is in contact with the divider shelf 9. The sixteenth surface 46 of the counter 11 is in contact with the floor surface 13. In FIG. 6, a portion 39 of the counter 11 that contacts the divider shelf 9 (i.e., the twelfth surface 42) is shown with hatching. A portion 39 of the counter 11 that contacts the floor surface 13 (i.e., the sixteenth surface 46) is also shown with hatching.

### Exposed Base Surface Area

The calculation unit 22 calculates an exposed base surface area AEB that is visible on each base surface 3. In the present embodiment, the calculation unit 22 calculates the exposed base surface area AEB for each of the first surface 31 through the sixth surface 36.

Specifically, in a case in which an opening 38 is provided in the base surface 3, the calculation unit 22 calculates, as the exposed base surface area AEB, a value obtained by subtracting the opening area of the opening 38 from the base surface area of the base surface 3. Examples of such openings 38 include areas where windows are provided and entrances without doors.

When a placed object 4 is arranged in contact with a base surface 3, the calculation unit 22 calculates, as the exposed base surface area AEB, a value obtained by subtracting a contact area of the portion 39 of the placed object 4 that contacts the base surface 3 from the base surface area of the base surface 3.

The exposed base surface area AEB of the second surface 32 will now be described with reference to FIG. 5. In FIG. 5, in the first surface 31 through the sixth surface 36, the portions 39 that are in contact with the placed objects 4 and the openings 38 are indicated by hatching.

The second surface 32 is provided with windows. Therefore, the surface area of the windows is subtracted from the surface area of the second surface 32. The kitchen counter 10 is in contact with the second surface 32. In the second surface 32, the portion 39 that is in contact with the kitchen counter 10 cannot be seen. Therefore, the contact area of the kitchen counter 10 on the second surface 32 is subtracted from the surface area of the second surface 32. Accordingly, the exposed base surface area AEB of the second surface 32 is a value obtained by subtracting the surface area of the windows and the contact area of the kitchen counter 10 from the surface area of the second surface 32.

In this manner, for a given surface, the value obtained by subtracting the opening area of the opening 38 and the contact area from the surface area of the base surface 3 is stored in the internal memory of the calculation unit 22 as the exposed base surface area AEB of that surface.

### Exposed Object Surface Area

The calculation unit 22 calculates an exposed object surface area AET, which corresponds to the visible portion of each placed object 4.

The calculation unit 22 calculates the surface area of at least one of the eleventh surface 41 through the sixteenth surface 46 of each placed object 4 as the exposed object surface area AET.

In one example, the calculation unit 22 calculates, as the exposed object surface area AET, the surface area of only surfaces of each placed object 4 that contribute to the color balance CB of the interior 1 (such surfaces will hereinafter be referred to as contributing surfaces). In the case of the dining table 15, the lower surface of the dining table 15 is not typically visible in daily use, and the side surfaces of the dining table 15 have a relatively small surface area. Accordingly, in the case of the dining table 15, the surface area of the top is calculated as the exposed object surface area AET. The surfaces to be used for surface area calculation for each placed object 4 are designated by the user operating the color balance calculation system 20.

The exposed object surface area AET of the counter 11 will now be described with reference to FIG. 6.

The counter 11 has an eleventh surface 41 through a sixteenth surface 46. The sixteenth surface 46 of the counter 11 is in contact with the first surface 31, which is the floor surface 13. The twelfth surface 42 of the counter 11 is in contact with the divider shelf 9. Accordingly, in the counter 11, the surfaces contributing to the color balance CB of the interior 1 are the eleventh surface 41, the thirteenth surface 43, the fourteenth surface 44, and the fifteenth surface 45. The exposed object surface area AET of the counter 11 is the total surface area of the eleventh surface 41, the thirteenth surface 43, the fourteenth surface 44, and the fifteenth surface 45.

### Color Families of Components

The calculation unit 22 has definitions of one or multiple color families. For example, the calculation unit 22 has, as color families, a first color family C1, a second color family C2, a first accent color family AC1, and a second accent color family AC2. The calculation unit 22 has a color range of each of the color families as a definition. Such definitions may be set by the user.

In one example, the first color family C1 is defined to include white and colors in the vicinity of white. The second color family C2 is defined to include beige and colors in the vicinity of beige. The first accent color family AC1 is defined to include gray and colors in the vicinity of gray. The second accent color family AC2 is defined to include green and colors in the vicinity of green.

The calculation unit 22 identifies the color family of the base surfaces 3 based on the colors of the base surfaces 3. The calculation unit 22 associates the base surfaces 3, the exposed base surface area AEB, and the color family of the base surfaces 3, and stores this association in the internal memory of the calculation unit 22. The calculation unit 22 also identifies the color family of each placed object 4 based on the color of the placed object 4. The calculation unit 22 associates the placed object 4, the exposed object surface area AET, and the color family of the placed object 4, and stores this association in the internal memory of the calculation unit 22.

The color families of the base surfaces 3 and the placed objects 4 may be defined by the user. In this case, the calculation unit 22 stores the color family defined by the user for each of the base surfaces 3 and the placed objects 4.

### Calculation of the Color Balance

Based on the exposed base surface areas AEB, the colors of the base surfaces 3, the exposed object surface areas AET, and the colors of the placed objects 4, the calculation unit 22 calculates the total surface area of the first color family C1, the total surface area of the second color family C2, and the total surface area of the accent color family AC serving as accents.

Specifically, the calculation unit 22 forms a set of components having colors belonging to a certain color family and computes the total exposed surface area of the components in that set. For example, the calculation unit 22 forms a set of components having colors belonging to the first color family C1 based on the data of all the components forming the interior 1. Then, the calculation unit 22 calculates the sum total of the exposed base surface areas AEB of the base surfaces 3 and the exposed object surface areas AET of the placed objects 4 included in the set of the components having colors belonging to the first color family C1. The calculation unit 22 stores the sum total calculated in this way in the internal memory as the total surface area of the first color family C1. Similarly, the calculation unit 22 stores, in the internal memory, the total surface area of the second color family C2, the total surface area of the first accent color family AC1, and the total surface area of the second accent color family AC2.

The calculation unit 22 calculates, as the color balance CB, the ratio of the total surface area of the first color family C1, the total surface area of the second color family C2, and the total surface area of the accent color family AC.

### Input Unit

The input unit 23 receives user inputs for operating the color balance calculation system 20. For example, the input unit 23 receives commands for selecting surfaces that contribute to the color balance CB of the target region AR in the placed objects 4.

### Output Unit

The output unit 24 outputs the calculation result of the color balance CB to devices. The devices include a personal computer, a display device 26, and a storage medium. In the present embodiment, the output unit 24 outputs the color balance CB to the display device 26. The calculation result of the color balance CB includes the surface area ratio of the first color family C1, the second color family C2, and the accent color family AC. The calculation result of the color balance CB may include the color family and the surface area of each of the first surface 31 through the sixth surface 36, and the color family and the surface area of the prescribed surfaces of each placed object 4. The prescribed surfaces of each of the placed objects 4 indicate surface areas of the surfaces contributing to the interior 1. For example, when the placed object 4 is a table, the prescribed surface is the eleventh surface 41 (i.e., the top surface).

The output unit 24 may output an input reception screen for receiving user inputs. An example of the input reception screen is a screen used to select surfaces of the placed objects 4 that contribute to the color balance CB of the target region AR. The input reception screen is configured to accept selection of the placed objects 4. Additionally, the input reception screen is configured to accept selection of one or more of the six surfaces of the selected placed object 4.

### Calculation Example

A calculation example of the color balance CB of the target region AR will now be described with reference to FIGS. 7 through 14.

The configuration of the interior 1 of the room 2, which is the target region AR, is as follows. The room 2, which is the target region AR, is surrounded by the first surface 31 through the sixth surface 36. In the room 2, which is the target region AR, the divider shelf 9, the kitchen counter 10, the counter 11, the cushions 12, the rug 14, the dining table 15, the potted plants 16, and the living room table 17 are arranged.

The first surface 31 (the floor surface 13) has a color belonging to the second color family C2. The colors belonging to the second color family C2 are beige-based colors. The second surface 32 has a color belonging to the first color family C1. The colors belonging to the first color family C1 are colors of a color system. The third surface 33 has a color belonging to the first color family C1. The fourth surface 34 has a color belonging to the first color family C1. The fifth surface 35 has a color belonging to the first color family C1. The sixth surface 36 has a color belonging to the first color family C1.

The rug 14 and the dining table 15 have colors belonging to the second color family C2. The divider shelf 9, the kitchen counter 10, the counter 11, and the cushions 12 have colors belonging to the first color family C1. The living room table 17 has a color belonging to the first accent color family AC1. The colors belonging to the first accent color family AC1 are gray-based colors. The potted plants 16 have colors belonging to the second accent color family AC2. The colors belonging to the second accent color family AC2 are green-based colors.

The kitchen counter 10 is disposed along the fourth surface 34. The twelfth surface 42 of the kitchen counter 10 is in contact with the third surface 33 of the room 2. The thirteenth surface 43 of the kitchen counter 10 is in contact with the second surface 32 of the room 2. The fifteenth surface 45 of the kitchen counter 10 is in contact with the fourth surface 34 of the room 2.

The counter 11 is disposed in the dining room 2B so as to come into contact with the divider shelf 9. The twelfth surface 42 of the counter 11 is in contact with the divider shelf 9. The sixteenth surface 46 (lower surface) of the counter 11 is in contact with the first surface 31 (floor surface 13) of the room 2.

The divider shelf 9 is disposed in the dining room 2B so as to come into contact with the counter 11. The sixteenth surface 46 (lower surface) of the divider shelf 9 is in contact with the first surface 31 (floor surface 13) of the room 2.

FIG. 7 is a table showing data used to calculate the exposed base surface area AEB of the first surface 31 (i.e., the floor surface 13).

As described above, in the room 2, which is the target region AR, the divider shelf 9, the kitchen counter 10, the counter 11, the cushions 12, the rug 14, the dining table 15, the potted plants 16, and the living room table 17 are arranged. The dining table 15 and the living room table 17 do not substantially cover the first surface 31 (i.e., the floor surface 13). Since the potted plants 16 and the cushions 12 are small articles, they do not substantially affect the exposed base surface area AEB of the first surface 31 (i.e., the floor surface 13). The kitchen counter 10, the counter 11, the rug 14, and the divider shelf 9 greatly affect the size of the exposed base surface area AEB of the first surface 31. The exposed base surface area AEB of the first surface 31 is calculated as a value obtained by subtracting the surface areas (contact areas) of the sixteenth surfaces 46 (lower surfaces) of the kitchen counter 10, the counter 11, the rug 14, and the divider shelf 9 from the base surface area of the first surface 31.

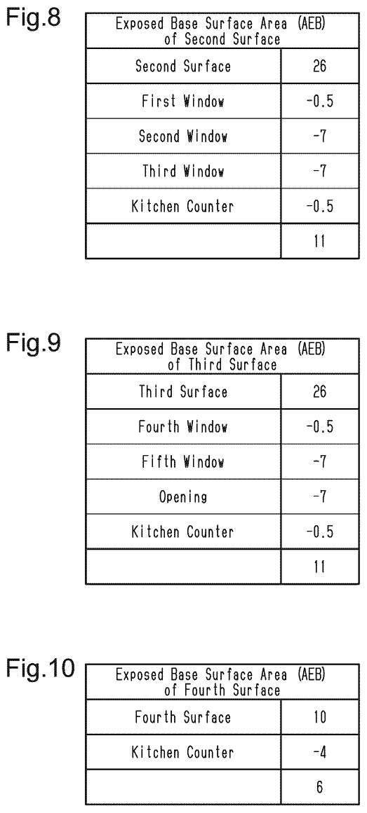

FIG. 8 is a table showing data used to calculate the exposed base surface area AEB of the second surface 32. The second surface 32 is provided with a first window 51, a second window 52, and a third window 53. The thirteenth surface 43 of the kitchen counter 10 is in contact with the second surface 32. Therefore, the exposed base surface area AEB of the second surface 32 is calculated by subtracting the opening areas of the first window 51, the second window 52, and the third window 53 from the base surface area of the second surface 32, and further subtracting the surface area (contact area) of the thirteenth surface 43 of the kitchen counter 10 from the obtained value.

FIG. 9 is a table showing data used to calculate the exposed base surface area AEB of the third surface 33. The third surface 33 is provided with a fourth window 54 and a fifth window 55. The third surface 33 is provided with an entrance 57. The twelfth surface 42 of the kitchen counter 10 is in contact with the third surface 33. Therefore, the exposed base surface area AEB of the third surface 33 is calculated by subtracting the opening areas of the fourth window 54 and the fifth window 55, the opening area of the entrance 57, and the surface area (contact area) of the twelfth surface 42 of the kitchen counter 10 from the base surface area of the third surface 33.

FIG. 10 is a table showing data used to calculate the exposed base surface area AEB of the fourth surface 34. The fifteenth surface 45 of the kitchen counter 10 is in contact with the fourth surface 34. Therefore, the exposed base surface area AEB of the fourth surface 34 is calculated by subtracting the surface area (contact area) of the fifteenth surface 45 of the kitchen counter 10 from the base surface area of the fourth surface 34.

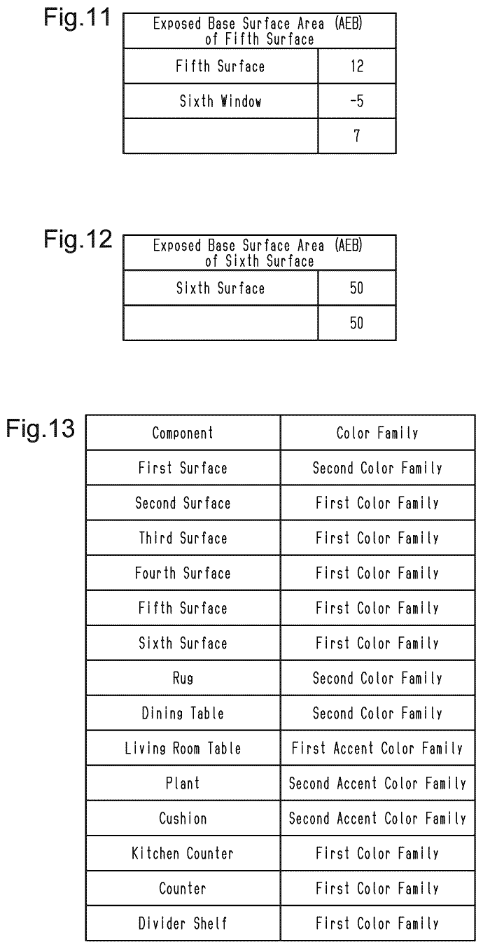

FIG. 11 is a table showing data used to calculate the exposed base surface area AEB of the fifth surface 35. The fifth surface 35 is provided with a sixth window 56. Therefore, the exposed base surface area AEB of the fifth surface 35 is calculated by subtracting the opening area of the sixth window 56 from the base surface area of the fifth surface 35.

FIG. 12 is a table showing data used to calculate the exposed base surface area AEB of the sixth surface 36 (i.e., the ceiling surface 7). The sixth surface 36 has no opening 38 and is not in contact with any other component. Therefore, the exposed base surface area AEB of the sixth surface 36 is equal to the base surface area of the sixth surface 36.

FIG. 13 is a table showing the color family of each of the components forming the interior 1. The data in the table of FIG. 13 is generated by the calculation unit 22. The data in the table of FIG. 13 may be generated by user input.

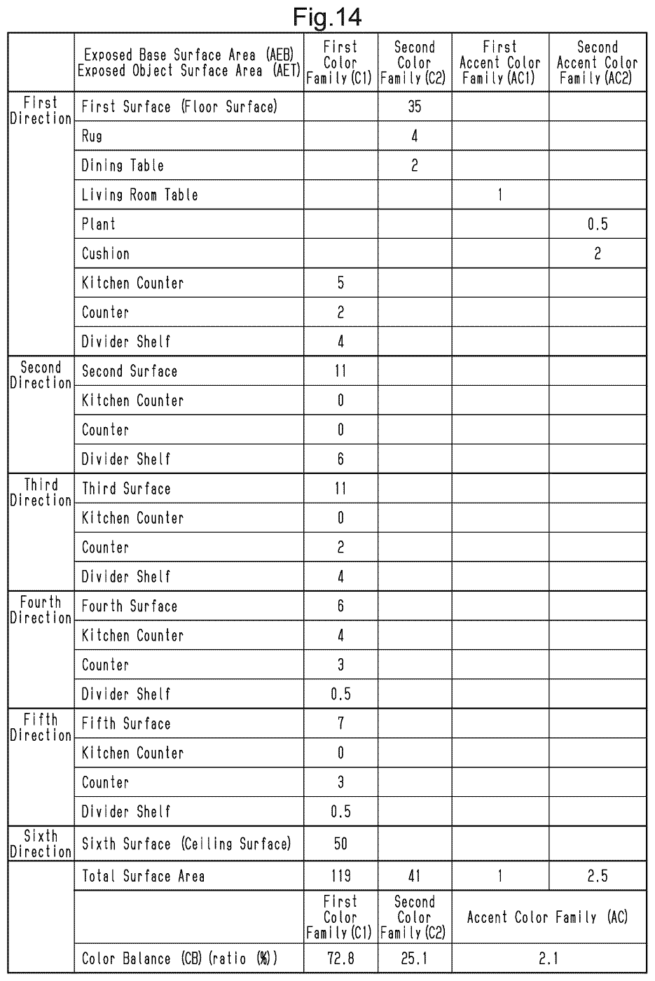

FIG. 14 is a table showing the exposed surface areas and the color families of the respective components when the target region AR is viewed from the first direction D1 through the sixth direction D6. The exposed surface areas include the exposed base surface area AEB and the exposed object surface area AET. The first direction DI is a direction facing the first surface 31. The section for the first direction D1 shows the exposed surface areas and the color families of the components that are visible when the floor surface 13 is viewed from above. The same applies to each of the second direction D2 through the sixth direction D6.

The table of FIG. 14 shows the total surface area of each color family. The table of FIG. 14 also shows the surface area ratio of the color families, calculated based on the total surface areas of the respective color families.

The color balance calculation system 20 may further include a color modification unit 25 that changes the colors of base surfaces 3 and the colors of placed objects 4.

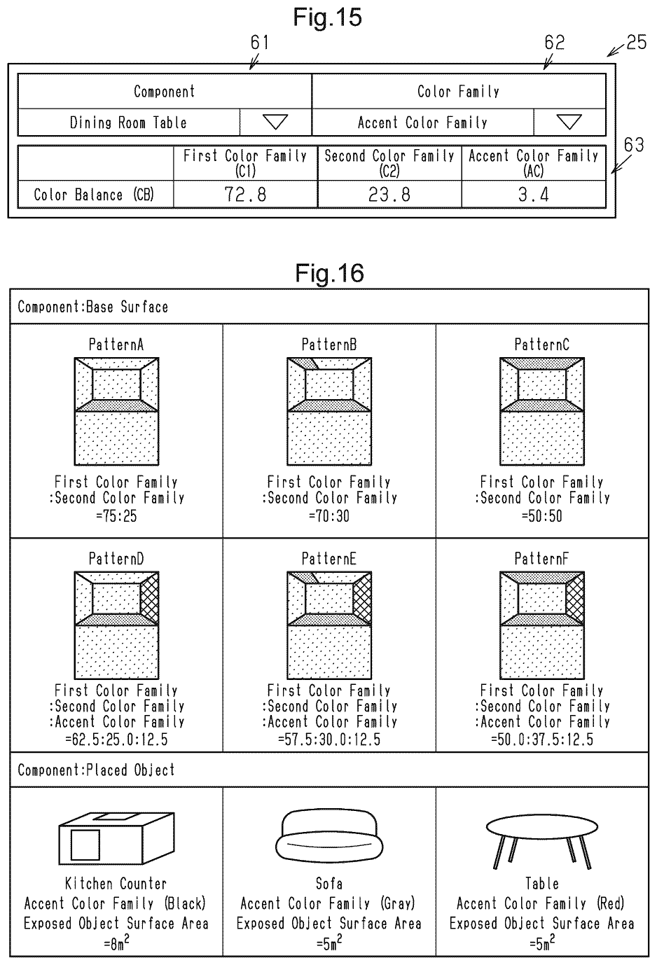

The color modification unit 25 will now be described with reference to FIG. 15. The color modification unit 25 is capable of changing the colors of the base surfaces 3 and the colors of the placed objects 4 selected by the user. The color modification unit 25 includes a component selection unit 61 that enables the user to select components of the interior 1. The component selection unit 61 presents components for user selection. The components include the first surface 31 through the sixth surface 36 as the base surfaces 3, and the placed objects 4 placed in the target region AR.

The color modification unit 25 includes a color selection unit 62 that allows the user to select a color family for the selected component. The color selection unit 62 presents, as selectable options, the first color family C1, the second color family C2, the first accent color family AC1, and the second accent color family AC2. The color modification unit 25 outputs the changed component and color to the calculation unit 22. The calculation unit 22 calculates the color balance CB based on the changed component and color. The color modification unit 25 includes a color balance display unit 63 to display the recalculated color balance CB. The values displayed by the color balance display unit 63 enable the user to understand how the color balance CB changes when the color family of the component is changed.

### Operation of the Present Embodiment

In the color coordination of the interior 1, the color balance CB of the colors is considered. Yet, the walls of the room 2, which is the target region AR, have complicated shapes. Additionally, a wide variety of placed objects 4 are disposed in the room 2 that defines the target region AR. Therefore, it is difficult to identify the value of the color balance CB. In the color coordination for the interior 1, colors for the interior 1 are determined based on subjective impressions of the designer or client without objectively identifying the color balance.

In the present technology, the color balance CB of the target region AR is expressed as numerical values. This facilitates objective evaluation of the color balance CB of the target region AR. Specifically, the color balance calculation system 20 includes the calculation unit 22, which calculates the color balance CB. Based on the exposed base surface areas AEB, the colors of the base surfaces 3, the exposed object surface areas AET, and the colors of the placed objects 4, the calculation unit 22 calculates the total surface area of the first color family C1, the total surface area of the second color family C2, and the total surface area of the accent color family AC. The calculation unit 22 then calculates, as the color balance CB, the ratio of the total surface area of the first color family C1, the total surface area of the second color family C2, and the total surface area of the accent color family AC. This configuration allows the color balance CB to be numerically identified. When the color balance CB is changed in the target region AR, the values before and after the change can be compared. As a result, the degree of changes in colors and the numerical variation facilitate adjustment of the color balance CB. Furthermore, compared to calculation of the color balance CB based solely on the surface areas of the base surfaces 3 and the placed objects 4, the color balance calculation system 20 calculates the color balance CB that is closer to human perception, thereby facilitating adjustment of the color balance CB.

### Advantages of the Present Embodiment

(1) The color balance calculation system 20 includes the acquisition unit 21 and the calculation unit 22, which calculates the color balance CB. Based on the exposed base surface areas AEB, the colors of the base surfaces 3, the exposed object surface areas AET, and the colors of the placed objects 4, the calculation unit 22 calculates the total surface area of the first color family C1, the total surface area of the second color family C2, and the total surface area of the accent color family AC.

The calculation unit 22 then calculates, as the color balance CB, the ratio of the total surface area of the first color family C1, the total surface area of the second color family C2, and the total surface area of the accent color family AC.

Further, the calculation of the surface areas of the accent color family AC may be omitted. Specifically, based on the exposed base surface areas AEB, the colors of the base surfaces 3, the exposed object surface areas AET, and the colors of the placed objects 4, the calculation unit 22 calculates the total surface area of the first color family C1 and the total surface area of the second color family C2. The calculation unit 22 may calculate, as the color balance CB, the ratio of the total surface area of the first color family Cl and the total surface area of the second color family C2.

With this configuration, the color balance CB of the target region AR can be calculated. Further, the color balance calculation system 20 calculates the color balance CB based on the exposed surface areas of visible portions of the base surfaces 3 and the placed objects 4. As a result, it is possible to calculate the color balance CB that more closely reflects human perception than a calculation based solely on the surface areas of the base surfaces 3 and the placed objects 4.

(2) When a placed object 4 is arranged in contact with a base surface 3, the calculation unit 22 calculates, as the exposed base surface area AEB, a value obtained by subtracting a contact area of the portion 39 of the placed object 4 that contacts the base surface 3 from the base surface area of the base surface 3. This configuration excludes portions of the base surface 3 that are not visible from the exposed base surface area AEB. This improves the accuracy of the color balance CB.

(3) In a case in which an opening 38 is provided in the base surface 3, the calculation unit 22 calculates, as the exposed base surface area AEB, a value obtained by subtracting the opening area of the opening 38 from the base surface area of the base surface 3. With this configuration, the opening 38 in the base surface 3 is excluded from the exposed base surface area AEB. This improves the accuracy of the color balance CB.

(4) In the color balance calculation system 20, each of the first surface 31, which forms the bottom surface of the target region AR, the second surface 32, which intersects the first surface 31, the third surface 33, which is located at the end opposite to the second surface 32, the fourth surface 34, which is connected to the second surface 32 and the third surface 33, the fifth surface 35, which is located at the end opposite to the fourth surface 34, and the sixth surface 36, which forms the ceiling surface of the target region AR, is defined as one of the base surfaces 3.

The surfaces facing the target region AR have complex shapes in practice. For example, in the room 2, which is the target region AR, certain portions of the pillars may protrude, portions may be recessed to accommodate window frames, or other portions may protrude to form spaces for accommodating ducts. As such, the surfaces facing the target region AR include irregularities. Accordingly, it is difficult to accurately calculate the exposed surface areas of the surfaces facing the target region AR. In this regard, according to the above-described configuration, the surfaces facing the target region AR are consolidated into six base surfaces 3. This configuration simplifies the calculation of the surface areas of the base surfaces 3 and the exposed base surface areas AEB.

(5) In the color balance calculation system 20, the surface of each placed object 4 viewed from the first direction D1, facing the first surface 31, is defined as the eleventh surface 41. The surface of the placed object 4 viewed from the second direction D2, facing the second surface 32, is defined as the twelfth surface 42. The surface of the placed object 4 viewed from the third direction D3, facing the third surface 33, is defined as the thirteenth surface 43. The surface of the placed object 4 viewed from the fourth direction D4, facing the fourth surface 34, is defined as the fourteenth surface 44. The surface of the placed object 4 viewed from the fifth direction D5, facing the fifth surface 35, is defined as the fifteenth surface 45. The surface of the placed object 4 viewed from the sixth direction D6, facing the sixth surface 36, is defined as the sixteenth surface 46. The calculation unit 22 calculates the surface area of at least one of the eleventh surface 41 through the sixteenth surface 46 of each placed object 4 as the exposed object surface area AET.

The surfaces of each placed object 4 have complex shapes in practice. For example, in the case of a counter 11 having a faucet, the counter 11 has a recess forming a sink. The divider shelf 9 includes multiple handles. Due to such surface irregularities of each placed object 4, it is difficult to accurately calculate the exposed surface area of the placed object 4. In this regard, according to the above-described configuration, the surfaces of each placed object 4 are consolidated into six surfaces. This configuration simplifies the calculation of the exposed object surface area AET of each placed object 4.

(6) The color balance calculation system 20 includes the color modification unit 25, which changes the colors of the base surfaces 3 and the colors of the placed objects 4. This configuration allows the color balance CB of the interior 1 of the target region AR to be readily changed.

(7) The color balance calculation system 20 may calculate the color balance CB for four or more color families.

### Modifications

The above-described embodiment exemplifies, without any intention to limit, an applicable form of the color balance calculation system 20. The color balance calculation system 20 is applicable to forms different from the example described in the above-described embodiment. For example, the structures of the above-described embodiment may be replaced, changed, or omitted in part or include additional elements. Modifications of the embodiment will now be described.

### First Modification

The color balance calculation system 20 may include a database of sample components. The user can simulate the interior 1 by selecting sample components from the database. The database contains several patterns of the base surfaces 3. Each of the patterns is configured such that the combination of colors of the first surface 31 through the sixth surface 36 surrounding the target region AR is different from that of other patterns. Each of the patterns has a different color balance CB. The user can select a pattern by referring to the color combination and the color balance CB. The database includes samples of several placed objects 4. Each sample of the placed objects 4 is associated with a color and an exposed object surface area AET. The user is allowed to select placed objects 4 to be arranged in the target region AR by referring to colors and the exposed object surface areas AET.

As shown in FIG. 16, the color balance calculation system 20 has patterns A through F. In each of the pattern A through the pattern F, the second surface 32 through the fourth surface 34 are set to have colors belonging to the first color family C1 (e.g., white). In each of the pattern A through the pattern F, the first surface 31 (i.e., the floor surface 13) is set to have a color belonging to the second color family C2 (e.g., beige). In the patterns A through F, the colors of the fifth surface 35 and the sixth surface 36 (i.e., the ceiling surface 7) are different.

In the pattern A, the sixth surface 36 is uniformly set to have a single color belonging to the first color family C1. The fifth surface 35 has a color belonging to the first color family C1.

In the pattern B, the sixth surface 36 is primarily set to a color belonging to the first color family C1, with portions having colors belonging to the second color family C2. The fifth surface 35 has a color belonging to the first color family C1.

In the pattern C, the sixth surface 36 is uniformly set to have a single color belonging to the second color family C2. The fifth surface 35 has a color belonging to the first color family C1.

In the pattern D, the sixth surface 36 is uniformly set to have a single color belonging to the first color family C1. The fifth surface 35 has a color belonging to the accent color family AC.

In the pattern E, the sixth surface 36 is primarily set to a color belonging to the first color family C1, with portions having colors belonging to the second color family C2. The fifth surface 35 has a color belonging to the accent color family AC.

In the pattern F, the sixth surface 36 is uniformly set to have a single color belonging to the second color family C2. The fifth surface 35 has a color belonging to the accent color family AC.

Simulation of the interior 1 is performed as follows. In the color balance calculation system 20, the size of the room 2, which includes the target region AR, is set. The type of the pattern and samples of the placed objects 4 are input into the color balance calculation system 20. The color balance calculation system 20 calculates the color balance based on the type of the pattern and the samples of the placed objects 4.

### Second Modification

The color balance calculation system 20 can also be implemented as a color balance calculation method. In the color balance calculation method, an operator uses a calculator to calculate the color balance CB. The operator uses the color balance calculation method to calculate the color balance CB of the interior 1 of a target region AR in a building. The color balance calculation method includes an acquisition step of acquiring interior data, which is data of the interior 1, and a calculation step of calculating the color balance CB based on the interior data. The interior data includes color information and shape information for each of multiple components forming the interior 1. The components include the base surfaces 3, facing the target region AR, and the objects 4 placed in the target region AR.

In the calculation step, the operator uses the calculator to calculate the total surface area of the first color family C1, the total surface area of the second color family C2, and the total surface area of the accent color family AC, which is an accent, based on the visible exposed base surface areas AEB of the base surfaces 3, the colors of the base surfaces 3, the visible exposed object surface areas AET of the placed objects 4, and the colors of the placed objects 4. In the calculation step, the operator calculates, as the color balance CB, the ratio of the total surface area of the first color family C1, the total surface area of the second color family C2, and the total surface area of the accent color family AC.

In the calculation step, the operator may omit the calculation of the surface areas of the accent color family AC. Specifically, in the calculation step, the operator uses the calculator to calculate the total surface area of the first color family C1 and the total surface area of the second color family C2, based on the visible exposed base surface areas AEB of the base surfaces 3, the colors of the base surfaces 3, the visible exposed object surface areas AET of the placed objects 4, and the colors of the placed objects 4. In the calculation step, the operator calculates, as the color balance CB, the ratio of the total surface area of the first color family C1 and the total surface area of the second color family C2.

With this configuration, the color balance CB of the target region AR can be calculated. Further, in the calculation step, the operator calculates the color balance CB based on the exposed surface areas of visible portions of the base surfaces 3 and the placed objects 4. As a result, it is possible to calculate the color balance CB that more closely reflects human perception than a calculation based solely on the surface areas of the base surfaces 3 and the placed objects 4.

### Third Modification

The color balance calculation system 20 can also be implemented as a color balance calculation program. The color balance calculation program causes a computer to calculate the color balance CB of the interior 1 of a target region AR in a building. The color balance calculation program includes an acquisition process of causing the computer to acquire interior data, which is data of the interior 1, and a calculation process of causing the computer to calculate the color balance CB based on the interior data. The interior data includes color information and shape information for each of multiple components forming the interior 1. The components include the base surfaces 3, facing the target region AR, and the objects 4 placed in the target region AR.

In the calculation process, the color balance calculation program causes the computer to calculate the total surface area of the first color family C1, the total surface area of the second color family C2, and the total surface area of the accent color family AC, which is an accent, based on the visible exposed base surface areas AEB of the base surfaces 3, the colors of the base surfaces 3, the visible exposed object surface areas AET of the placed objects 4, and the colors of the placed objects 4. The color balance calculation program causes the computer to calculate, as the color balance CB, the ratio of the total surface area of the first color family C1, the total surface area of the second color family C2, and the total surface area of the accent color family AC.

In the calculation process, the calculation of the surface areas of the accent color family AC may be omitted. Specifically, the color balance calculation program causes the computer to calculate the total surface area of the first color family C1 and the total surface area of the second color family C2, based on the visible exposed base surface areas AEB of the base surfaces 3, the colors of the base surfaces 3, the visible exposed object surface areas AET of the placed objects 4, and the colors of the placed objects 4. The color balance calculation program causes the computer to calculate, as the color balance CB, the ratio of the total surface area of the first color family C1 and the total surface area of the second color family C2.

With this configuration, the color balance CB of the target region AR can be calculated. It is also possible to cause the computer to calculate the color balance CB based on the exposed surface areas of visible portions of the base surfaces 3 and the placed objects 4. As a result, it is possible to cause the computer to calculate the color balance CB that more closely reflects human perception than a calculation based solely on the surface areas of the base surfaces 3 and the placed objects 4.

### Modification of Color Balance Calculation System

The color balance calculation system 20 may be a single information processing device (e.g., a computer) or may be distributed across multiple devices (e.g., computers) or subsystems that cooperate with each other to execute programs.

The color balance calculation system 20 may include one or more processors; and a memory. The memory may be used to store computer program instructions or code organized into one or more modules and written in any desired computer programming language. When executed by, for example, the one or more processors, the instructions may cause the system to implement one or more of the methods or processes or to perform operations, described herein.

Acquisition unit 21, calculation unit 22, and color modification unit 25 of the color balance calculation system may be configured as circuitry including (1) one or more processors that execute various processes in accordance with computer programs (software); (2) one or more dedicated hardware circuits, such as application-specific integrated circuits (ASICs), that perform at least part of the various processes; or (3) a combination thereof.

### Modification of Memory

Each of the memory, the internal memory and the storage medium of the system according to the present disclosure is a computer-readable storage medium and includes a non-transitory computer-readable medium. Examples of the memory include, but are not limited to, a ROM, a hard disk, storage, a removable medium, flash memory, a memory stick, an optical medium, a magneto-optical medium, and a CD-ROM.

### Modification of Processor

Examples of one or more processors included in the system according to the present disclosure include, but are not limited to, a central processing unit (CPU), a graphics processing unit (GPU), an accelerated processing unit (APU), a neural network processing unit (NPU), a microprocessor, a microcontroller, a digital signal processor (DSP), a field-programmable gate array (FPGA), a complex programmable logic device (CPLD), another type of processor such as a general-purpose processor, an application-specific integrated circuit (ASIC), or any combination thereof configured to execute the functions described in this specification.

This specification further discloses the following techniques.

### Clause 1

A color balance calculation system calculates a color balance of an interior of a target region in a building. The system includes an acquisition unit that acquires interior data representing the interior, and a calculation unit that calculates the color balance based on the interior data. The interior data includes color information and shape information of each of multiple components forming the interior. The components include a base surface facing the target region, and a placed object arranged in the target region. The calculation unit calculates a total surface area of a first color family and a total surface area of a second color family based on a visible exposed base surface area of the base surface, a color of the base surface, a visible exposed object surface area of the placed object, and a color of the placed object, and further calculates, as the color balance, a ratio of the total surface area of the first color family and the total surface area of the second color family.

Alternatively, the calculation unit calculates the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculates, as the color balance, a ratio of the total surface area of the first color family, the total surface area of the second color family, and the total surface area of the accent color family.

### Clause 2

In the color balance calculation system according to clause 1, in a case in which the placed object is placed so as to be in contact with the base surface, the calculation unit calculates, as the exposed base surface area, a value obtained by subtracting a contact area of a portion of the placed object that is in contact with the base surface from a base surface area of the base surface.

### Clause 3

In the color balance calculation system according to clause 2, in a case in which an opening is provided in the base surface, the calculation unit calculates, as the exposed base surface area, a value obtained by subtracting an opening area of the opening from the base surface area of the base surface.

### Clause 4

In the color balance calculation system according to any one of clauses 1 to 3, each of a first surface forming a bottom surface of the target region, a second surface intersecting the first surface, a third surface located at an end opposite to the second surface, a fourth surface connected to the second surface and the third surface, a fifth surface located at an end opposite to the fourth surface, and a sixth surface forming a ceiling surface of the target region is defined as the base surface.

### Clause 5

In the color balance calculation system according to clause 4, a surface of the placed object viewed from a first direction facing the first surface is defined as an eleventh surface.

A surface of the placed object viewed from a second direction facing the second surface is defined as a twelfth surface.

A surface of the placed object viewed from a third direction facing the third surface is defined as a thirteenth surface.

A surface of the placed object viewed from a fourth direction facing the fourth surface is defined as a fourteenth surface.

A surface of the placed object viewed from a fifth direction facing the fifth surface is defined as a fifteenth surface.

A surface of the placed object viewed from a sixth direction facing the sixth surface is defined as a sixteenth surface.

The calculation unit calculates, as the exposed object surface area, a surface area of at least one of the eleventh surface through the sixteenth surface of the placed object.

### Clause 6

The color balance calculation system according to any one of clauses 1 to 5, further includes a color modification unit that changes the color of the base surface and the color of the placed object.

### Clause 7

A color balance calculation system calculates a color balance of an interior of a target region in a building. The system includes an acquisition unit that acquires interior data representing the interior, and a calculation unit that calculates the color balance based on the interior data. The interior data includes color information and shape information of each of multiple components forming the interior. The components include a base surface facing the target region, and a placed object arranged in the target region. The calculation unit calculates, as the color balance, a ratio of surface areas of multiple color families based on a visible exposed base surface area of the base surface, a color of the base surface, a visible exposed object surface area of the placed object, and a color of the placed object.

### Clause 8

A color balance calculation method calculates a color balance of an interior of a target region in a building. The method includes an acquisition step that acquires interior data representing the interior, and a calculation step that calculates the color balance based on the interior data. The interior data includes color information and shape information of each of multiple components forming the interior. The components include a base surface facing the target region, and a placed object arranged in the target region. The calculation step calculates a total surface area of a first color family and a total surface area of a second color family based on a visible exposed base surface area of the base surface, a color of the base surface, a visible exposed object surface area of the placed object, and a color of the placed object, and further calculates, as the color balance, a ratio of the total surface area of the first color family and the total surface area of the second color family.

Alternatively, the calculation step calculates the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculates, as the color balance, a ratio of the total surface area of the first color family, the total surface area of the second color family, and the total surface area of the accent color family.

### Clause 9

A color balance calculation program causes a computer to calculate a color balance of an interior of a target region in a building. The program includes an acquisition process that causes the computer to acquire interior data representing the interior, and a calculation process that causes the computer to calculate the color balance based on the interior data. The interior data includes color information and shape information of each of multiple components forming the interior. The components include a base surface facing the target region, and a placed object arranged in the target region. The calculation process causes the computer to calculate a total surface area of a first color family and a total surface area of a second color family based on a visible exposed base surface area of the base surface, a color of the base surface, a visible exposed object surface area of the placed object, and a color of the placed object, and further calculate, as the color balance, a ratio of the total surface area of the first color family and the total surface area of the second color family.

Alternatively, the calculation process causes the computer to calculate the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculate, as the color balance, a ratio of the total surface area of the first color family, the total surface area of the second color family, and the total surface area of the accent color family.

### Clause A1

A color balance calculation system that is configured to calculate a color balance of an interior of a target region in a building, the system including:
one or more processors; and
a memory storing instructions that when executed by the one or more processors cause the system to perform operations including:
acquiring interior data representing the interior; and
calculating the color balance based on the interior data, wherein
the interior data includes color information and shape information of each of multiple components forming the interior,
the components include:
   a base surface facing the target region; and
   a placed object arranged in the target region, and the calculating the color balance includes
   calculating a total surface area of a first color family and a total surface area of a second color family based on a visible exposed base surface area of the base surface, a color of the base surface, a visible exposed object surface area of the placed object, and a color of the placed object, and further calculating, as the color balance, a ratio of the total surface area of the first color family and the total surface area of the second color family, or
   calculating the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculating, as the color balance, a ratio of the total surface area of the first color family, the total surface area of the second color family, and the total surface area of the accent color family.

### Clause A2

The color balance calculation system according to clause A1, wherein
in a case in which the placed object is placed so as to be in contact with the base surface, the calculating the color balance includes calculating, as the exposed base surface area, a value obtained by subtracting a contact area of a portion of the placed object that is in contact with the base surface from a base surface area of the base surface.

### Clause A3

The color balance calculation system according to clause A2, wherein
in a case in which an opening is provided in the base surface, the calculating the color balance includes calculating, as the exposed base surface area, a value obtained by subtracting an opening area of the opening from the base surface area of the base surface.

### Clause A4

The color balance calculation system according to clause A1, wherein each of a first surface forming a bottom surface of the target region, a second surface intersecting the first surface, a third surface located at an end opposite to the second surface, a fourth surface connected to the second surface and the third surface, a fifth surface located at an end opposite to the fourth surface, and a sixth surface forming a ceiling surface of the target region is defined as the base surface.

### Clause A5

The color balance calculation system according to clause A4, wherein
a surface of the placed object viewed from a first direction facing the first surface is defined as an eleventh surface,
a surface of the placed object viewed from a second direction facing the second surface is defined as a twelfth surface,
a surface of the placed object viewed from a third direction facing the third surface is defined as a thirteenth surface,
a surface of the placed object viewed from a fourth direction facing the fourth surface is defined as a fourteenth surface,
a surface of the placed object viewed from a fifth direction facing the fifth surface is defined as a fifteenth surface,
a surface of the placed object viewed from a sixth direction facing the sixth surface is defined as a sixteenth surface, and
the calculating the color balance includes calculating, as the exposed object surface area, a surface area of at least one of the eleventh surface, the twelfth surface, the thirteenth surface, the fourteenth surface, the fifteenth surface, or the sixteenth surface of the placed object.

### Clause A6

The color balance calculation system according to clause A1, wherein the operations further include changing the color of the base surface and the color of the placed object.

### Clause A7

A color balance calculation system that is configured to calculate a color balance of an interior of a target region in a building, the system including:
one or more processors; and
a memory storing instructions that when executed by the one or more processors cause the system to perform operations including:
acquiring interior data representing the interior; and
calculating the color balance based on the interior data, wherein
the interior data includes color information and shape information of each of multiple components forming the interior,
the components include:
   a base surface facing the target region; and
   a placed object arranged in the target region, and
the calculating the color balance includes calculating, as the color balance, a ratio of surface areas of multiple color families based on a visible exposed base surface area of the base surface, a color of the base surface, a visible exposed object surface area of the placed object, and a color of the placed object.

### Clause A8

A color balance calculation method of calculating a color balance of an interior of a target region in a building, the method including:
acquiring interior data representing the interior; and
calculating the color balance based on the interior data, wherein
the interior data includes color information and shape information of each of multiple components forming the interior,
the components include:
   a base surface facing the target region; and
   a placed object arranged in the target region, and the calculating the color balance includes
   calculating a total surface area of a first color family and a total surface area of a second color family based on a visible exposed base surface area of the base surface, a color of the base surface, a visible exposed object surface area of the placed object, and a color of the placed object, and further calculating, as the color balance, a ratio of the total surface area of the first color family and the total surface area of the second color family, or
   calculating the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculating, as the color balance, a ratio of the total surface area of the first color family, the total surface area of the second color family, and the total surface area of the accent color family.

### Clause A9

A non-transitory computer readable medium storing a color balance calculation program that is configured to cause a computer to calculate a color balance of an interior of a target region in a building, the program being configured to cause the computer to execute:
acquiring interior data representing the interior; and
calculating the color balance based on the interior data, wherein
the interior data includes color information and shape information of each of multiple components forming the interior,
the components include:
   a base surface facing the target region; and
   a placed object arranged in the target region, and the calculating the color balance includes
   calculating a total surface area of a first color family and a total surface area of a second color family based on a visible exposed base surface area of the base surface, a color of the base surface, a visible exposed object surface area of the placed object, and a color of the placed object, and further calculating, as the color balance, a ratio of the total surface area of the first color family and the total surface area of the second color family, or
   calculating the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculating, as the color balance, a ratio of the total surface area of the first color family, the total surface area of the second color family, and the total surface area of the accent color family.

### REFERENCE SIGNS LIST

AC) Accent Color Family; AEB) Exposed Base Surface Area; AET) Exposed Object Surface Area; AR) Target Region; C1) First Color Family; C2) Second Color Family; CB) Color Balance; D1) First Direction; D2) Second Direction; D3) Third Direction; D4) Fourth Direction; D5) Fifth Direction; D6) Sixth Direction; 1) Interior; 3) Base Surface; 4) Placed Object; 7) Roof Surface; 20) Color Balance Calculation System; 21) Acquisition Unit; 22) Calculation Unit; 25) Color Modification Unit; 31) First Surface; 32) Second Surface; 33) Third Surface; 34) Fourth Surface; 35) Fifth Surface; 36) Sixth Surface; 38) Opening; 39) Portion; 41) Eleventh Surface; 42) Twelfth Surface; 43) Thirteenth Surface; 44) Fourteenth Surface; 45) Fifteenth Surface; 46) Sixteenth Surface.

1. A color balance calculation system that is configured to calculate a color balance of an interior of a target region in a building, the system comprising:
an acquisition unit that is configured to acquire interior data representing the interior; and
a calculation unit that is configured to calculate the color balance based on the interior data, wherein
the interior data includes color information and shape information of each of multiple components forming the interior,
the components include:
a base surface facing the target region; and
a placed object arranged in the target region, and the calculation unit
is configured to calculate a total surface area of a first color family and a total surface area of a second color family based on a visible exposed base surface area of the base surface, a color of the base surface, a visible exposed object surface area of the placed object, and a color of the placed object, and is further configured to calculate, as the color balance, a ratio of the total surface area of the first color family and the total surface area of the second color family, or
is configured to calculate the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and is further configured to calculate, as the color balance, a ratio of the total surface area of the first color family, the total surface area of the second color family, and the total surface area of the accent color family.

2. The color balance calculation system according to claim 1, wherein
in a case in which the placed object is placed so as to be in contact with the base surface, the calculation unit is configured to calculate, as the exposed base surface area, a value obtained by subtracting a contact area of a portion of the placed object that is in contact with the base surface from a base surface area of the base surface.

3. The color balance calculation system according to claim 2, wherein
in a case in which an opening is provided in the base surface, the calculation unit is configured to calculate, as the exposed base surface area, a value obtained by subtracting an opening area of the opening from the base surface area of the base surface.

4. The color balance calculation system according to claim 1, wherein each of a first surface forming a bottom surface of the target region, a second surface intersecting the first surface, a third surface located at an end opposite to the second surface, a fourth surface connected to the second surface and the third surface, a fifth surface located at an end opposite to the fourth surface, and a sixth surface forming a ceiling surface of the target region is defined as the base surface.

5. The color balance calculation system according to claim 4, wherein
a surface of the placed object viewed from a first direction facing the first surface is defined as an eleventh surface,
a surface of the placed object viewed from a second direction facing the second surface is defined as a twelfth surface,
a surface of the placed object viewed from a third direction facing the third surface is defined as a thirteenth surface,
a surface of the placed object viewed from a fourth direction facing the fourth surface is defined as a fourteenth surface,
a surface of the placed object viewed from a fifth direction facing the fifth surface is defined as a fifteenth surface,
a surface of the placed object viewed from a sixth direction facing the sixth surface is defined as a sixteenth surface, and
the calculation unit is configured to calculate, as the exposed object surface area, a surface area of at least one of the eleventh surface, the twelfth surface, the thirteenth surface, the fourteenth surface, the fifteenth surface, or the sixteenth surface of the placed object.

6. The color balance calculation system according to claim 1, further comprising a color modification unit that is configured to change the color of the base surface and the color of the placed object.

7. A color balance calculation system that is configured to calculate a color balance of an interior of a target region in a building, the system comprising:
an acquisition unit that is configured to acquire interior data representing the interior; and
a calculation unit that is configured to calculate the color balance based on the interior data, wherein
the interior data includes color information and shape information of each of multiple components forming the interior,
the components include:
a base surface facing the target region; and
a placed object arranged in the target region, and
the calculation unit is configured to calculate, as the color balance, a ratio of surface areas of multiple color families based on a visible exposed base surface area of the base surface, a color of the base surface, a visible exposed object surface area of the placed object, and a color of the placed object.

8. A color balance calculation method of calculating a color balance of an interior of a target region in a building, the method comprising:
acquiring interior data representing the interior; and
calculating the color balance based on the interior data, wherein
the interior data includes color information and shape information of each of multiple components forming the interior,
the components include:
a base surface facing the target region; and
a placed object arranged in the target region, and the calculating the color balance includes
calculating a total surface area of a first color family and a total surface area of a second color family based on a visible exposed base surface area of the base surface, a color of the base surface, a visible exposed object surface area of the placed object, and a color of the placed object, and further calculating, as the color balance, a ratio of the total surface area of the first color family and the total surface area of the second color family, or
calculating the total surface area of the first color family, the total surface area of the second color family, and a total surface area of an accent color family that is an accent, based on the visible exposed base surface area of the base surface, the color of the base surface, the visible exposed object surface area of the placed object, and the color of the placed object; and further calculating, as the color balance, a ratio of the total surface area of the first color family, the total surface area of the second color family, and the total surface area of the accent color family.
